(19) United States
(12) Patent Application Publication
(10) Pub. No.: US 2019/0221771 A1
(43) Pub. Date: Jul. 18, 2019

(54) BUFFER LAYER FOR ORGANIC LIGHT EMITTING DEVICES AND METHOD OF MAKING THE SAME

(71) Applicant: Universal Display Corporation, Ewing, NJ (US)

(72) Inventors: Siddharth Harikrishna Mohan, Plainsboro, NJ (US); William E. Quinn, Whitehouse Station, NJ (US); James Robert Kantor, Belle Mead, NJ (US)

(21) Appl. No.: 16/361,317

(22) Filed: Mar. 22, 2019

Related U.S. Application Data
(62) Division of application No. 15/331,065, filed on Oct. 21, 2016.
(60) Provisional application No. 62/245,088, filed on Oct. 22, 2015.

(51) Int. Cl. H01L 51/52

(52) U.S. Cl. CPC H01L 51/5253; H01L 2251/303

(57) ABSTRACT

A buffer layer is provided that can be fabricated over an OLED without the use of any oxygen-containing gas. The buffer layer reduces the possibility of damage to the underlying OLED due to use of oxygen-containing materials during deposition of subsequent barrier layers, and thereby allows for deposition of barrier layers without reducing the flexibility of the device.

### CROSS-REFERENCE TO RELATED APPLICATIONS

This application claims the benefit of U.S. Provisional Patent Application Ser. No. 62/245,088, filed Oct. 22, 2015, the entire contents of which is incorporated herein by reference.

### PARTIES TO A JOINT RESEARCH AGREEMENT

The claimed invention was made by, on behalf of, and/or in connection with one or more of the following parties to a joint university corporation research agreement: Regents of the University of Michigan, Princeton University, University of Southern California, and the Universal Display Corporation. The agreement was in effect on and before the date the claimed invention was made, and the claimed invention was made as a result of activities undertaken within the scope of the agreement.

### FIELD OF THE INVENTION

The present invention relates to buffer layers and arrangement suitable for use with devices such as organic light emitting diodes and other devices, including the same.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

One application for phosphorescent emissive molecules is a full color display. Industry standards for such a display call for pixels adapted to emit particular colors, referred to as “saturated” colors. In particular, these standards call for saturated red, green, and blue pixels. Color may be measured using CIE coordinates, which are well known to the art.

One example of a green emissive molecule is tris(2-phenylpyridine) iridium, denoted Ir(ppy)₃, which has the following structure:

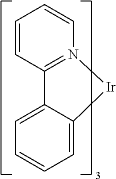

In this, and later figures herein, we depict the dative bond from nitrogen to metal (here, Ir) as a straight line.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

More details on OLEDs, and the definitions described above, can be found in U.S. Pat. No. 7,279,704, which is incorporated herein by reference in its entirety.

### SUMMARY OF THE INVENTION

In an embodiment, a device is provided that includes a substrate, an OLED disposed over the substrate, the OLED comprising a cathode, an anode, and an organic emissive material disposed between the cathode and the anode, a first buffer layer disposed over the OLED, and a barrier layer disposed over the buffer layer. The first barrier layer may include one or more materials selected from the group consisting of: a metal oxide, a hybrid organic-inorganic oxide, a metal nitride, a metal oxy-nitride, a metal carbide, a metal oxy-boride barrier material, and a combination thereof, and the buffer layer may consist essentially of one or more materials that is fabricable without the use of an oxygen-containing gas. The buffer layer may prevent interaction of materials used to deposit the first barrier layer with one or more layers of the OLED. A second barrier layer may be disposed over the first barrier layer. The buffer layer may encapsulate the OLED against the substrate. It may be amorphous or polycrystalline. The buffer layer, or each portion of the buffer layer, may have a thickness of 5 nm-1500 nm, more preferably 5 nm-500 nm.

The buffer layer may include one or more materials selected from the group consisting of: a metal, a metal oxide, a metal nitride, a metal oxy-nitride, a metal carbide, a metal oxy-boride, and a hybrid organic-inorganic material. Suitable metals include Al, Ni, Cr, Au, Ti, Pt, Ag, Mg, Yb and combinations thereof. Suitable metal oxides include silicon oxide, aluminum oxide, indium oxide, tin oxide, zinc oxide, indium tin oxide, indium zinc oxide, aluminum zinc oxide, zinc tin oxide, tantalum oxide, zirconium oxide, niobium oxide, molybdenum oxide and combinations thereof. Suitable metal nitrides include silicon nitride, aluminum nitride, boron nitride, titanium nitride, and a combination thereof. Suitable metal oxy-nitrides include aluminum oxy-nitride, silicon oxy-nitride, boron oxy-nitride and combinations thereof. Suitable metal carbides include tungsten carbide, boron carbide, silicon carbide and combinations thereof. Suitable metal oxy-borides include zirconium oxy-boride, titanium oxy-boride and combinations thereof.

Suitable hybrid organic-inorganic materials include SiOxCyHz, SiOxNyHz, SiOxNyCz, SiOxNyCz,H, SiOxCyHzF, SiOxNyHzF, SiOxNyCzF, SiOxNyCz,HaF, AlOxCyHz, AlOxNyHz, AlOxNyCz, AlOxNyCz,H, AlOxCyHzF, AlOxNyHzF, AlOxNyCzF, AlOxNyCz,HaF, ZnOxCyHz, ZnOxNyHz, ZnOxNyCz, ZnOxNyCz,H, ZnOxCyHzF, ZnOxNyHzF, ZnOxNyCzF, ZnOxNyCz,HaF, TiOxCyHz, TiOxNyHz, TiOxNyCz, TiOxNyCz,H, TiOxCyHzF, TiOxNyHzF, TiOxNyCzF, TiOxNyCz,HaF, and combinations thereof.

In an embodiment, a method of fabricating a device is provided that includes depositing a buffer layer over an OLED disposed on a substrate, and depositing a first barrier layer over the buffer layer, the first barrier layer comprising one or more materials of a metal oxide, a hybrid organic-inorganic oxide, a metal nitride, a metal oxy-nitride, a metal carbide, a metal oxy-boride barrier material, or a combination thereof. The buffer layer may consist essentially of one or more materials that is fabricable without the use of an oxygen-containing gas. The buffer layer may be deposited at a temperature lower than a glass transition temperature of an organic material disposed within the OLED. The first barrier layer may be deposited in the same chamber as the buffer layer without removing the OLED and the buffer layer from the chamber. A second barrier layer may be deposited over the first barrier layer. The buffer layer and the first barrier layer may be deposited using the same process. The buffer layer may include multiple materials.

The buffer layer may be deposited using a variety of techniques, including physical vapor deposition (PVD), chemical vapor deposition (CVD), plasma polymerization, and combinations thereof. Suitable PVD processes include sputtering, evaporation, and e-beam deposition, and combinations thereof. Suitable PVD process targets include Al, Ni, Cr, Au, Ti, Pt, Ag, Mg, Yb, silicon oxide, aluminum oxide, indium oxide, tin oxide, zinc oxide, indium tin oxide, indium zinc oxide, aluminum zinc oxide, tantalum oxide, zirconium oxide, niobium oxide, molybdenum oxide, silicon nitride, aluminum nitride, boron nitride, titanium nitride, aluminum oxy-nitride, silicon oxy-nitride, boron oxy-nitride, tungsten carbide, boron carbide, silicon carbide, zirconium oxy-boride, titanium oxy-boride and combinations thereof. Suitable CVD processes include atomic layer deposition (ALD), plasma enhanced chemical vapor deposition (PECVD), and plasma assisted atomic layer deposition and combinations thereof. Suitable CVD process precursors include hexamethyl disiloxane (HMDSO) and tetrathylorthosilicate (TEOS); methylsilane; dimethylsilane (DMS); vinyl trimethylsilane; trimethylsilane; tetramethylsilane; ethylsilane; disilanomethane; bis(methylsilano)methane; 1,2-disilanoethane; 1,2-bis(methylsilano)ethane; 2,2-disilanopropane; 1,3,5-trisilano-2,4,6-trimethylene; dimethylphenylsilane; diphenylmethylsilane; tetraethylortho silicate; dimethyldimethoxysilane; 1,3,5,7-tetramethylcyclotetrasiloxane; 1,3-dimethyldisiloxane; 1,1,3,3-tetramethyldisiloxane; 1,3-bis(silanomethylene)disiloxane; bis(1-methyldisiloxanyl)methane; 2,2-bis(1-methyldisiloxanyl)propane; 2,4,6,8-tetramethylcyclotetrasiloxane; octamethylcyclotetrasiloxane; 2,4,6,8,10-pentamethylcyclopentasiloxane; 1,3,5,7-tetrasilano-2,6-dioxy-4,8-dimethylene; hexamethylcyclotrisiloxane; 1,3,5,7,9-pentamethylcyclopentasiloxane; hexamethoxydisiloxane; hexamethyldisilazane (HMDS); divinyltetramethyldisilizane; hexamethylcyclotrisilazane; dimethylbis(Nmethylacetamido)silane; dimethylbis-(N-ethylacetamido)silane; methylvinylbis(Nmethylacetamido)silane; methylvinylbis(N-butylacetamido)silane; methyltris(Nphenylacetamido)silane; vinyltris(N-ethylacetamido)silane; tetrakis(N-methylacetamido)silane; diphenylbis(diethylaminoxy)silane; methyltris(diethylaminoxy)silane; and bis(trimethylsilyl)carbodiimide, diethyl zinc, dimethyl zinc, zinc acetate, titanium tetrachloride, tetrakis-dimethylamidotitanium (TDMAT) and tetrakis-diethylamidotitanium(TDEAT), titanium ethoxide, titanium isopropoxide, titanium tetraisopropoxide, aluminum isopropoxide, trimethyl aluminum, dimethyltin diacetate, zinc acetylacetonate, zirconium hexafluoroacetylacetonate, trimethyl indium, triethyl indium, cerium (IV) (2,2,6,6-tetramethyl-3,5-heptanedionate), and zinc carbamate and combinations thereof.

### BRIEF DESCRIPTION OF THE DRAWINGS

FIG. 1 shows an organic light emitting device.

FIG. 2 shows an inverted organic light emitting device that does not have a separate electron transport layer.

FIG. 3A shows a schematic illustration of an OLED encapsulated with a direct encapsulation technique.

FIG. 3B shows a schematic illustration of an OLED encapsulated with an indirect encapsulation technique.

FIG. 3C shows a schematic illustration of an OLED encapsulated with a combination of direct and indirect encapsulation techniques.

FIG. 4 shows a schematic illustration of a buffer layer according to an embodiment of the invention.

FIG. 5A shows a photograph of a reference device at t=0 hours.

FIG. 5B shows a photograph of a device including a buffer layer according to an embodiment of the invention at t=0 hours.

FIG. 6A shows a photograph of the reference device of FIG. 5A at t=0 hours under high magnification.

FIG. 6B shows a photograph of the device of FIG. 5B at t=0 hours under high magnification.

FIG. 7A shows a photograph of the reference device of FIGS. 5A and 6A at t=226 hours.

FIG. 7B shows a photograph of the device of FIGS. 5B and 6B at t=226 hours.

### DETAILED DESCRIPTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), which are incorporated by reference in their entireties. Phosphorescence is described in more detail in U.S. Pat. No. 7,279,704 at cols. 5-6, which are incorporated by reference.

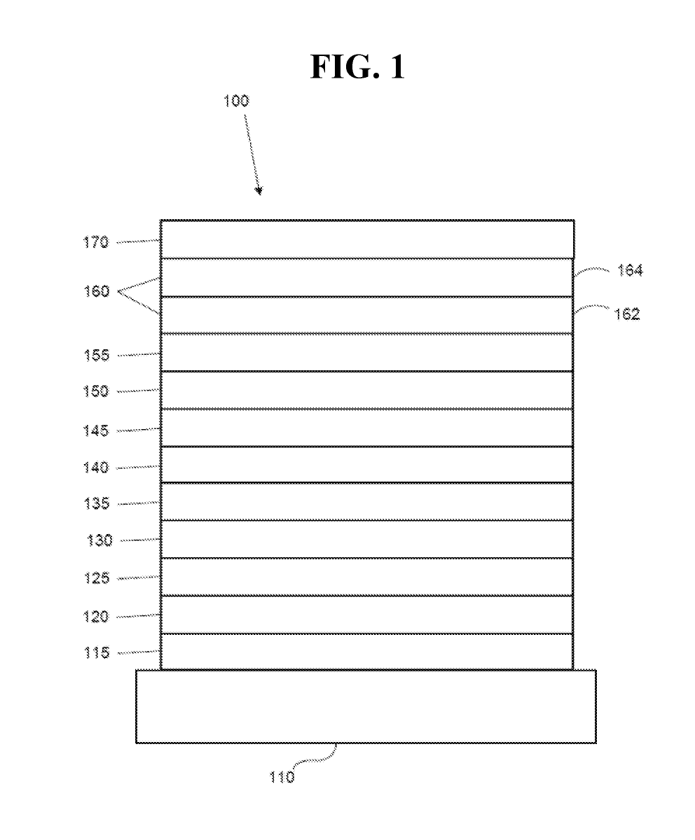

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

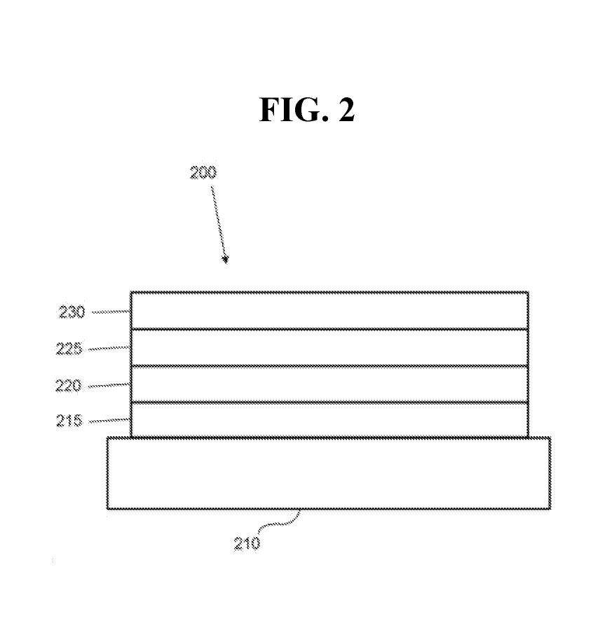

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. Such consumer products would include any kind of products that include one or more light source(s) and/or one or more of some type of visual displays. Some examples of such consumer products include flat panel displays, computer monitors, medical monitors, televisions, billboards, lights for interior or exterior illumination and/or signaling, heads-up displays, fully or partially transparent displays, flexible displays, laser printers, telephones, cell phones, tablets, phablets, personal digital assistants (PDAs), laptop computers, digital cameras, camcorders, viewfinders, micro-displays, virtual reality displays, augmented reality displays, 3-D displays, vehicles, a large area wall, theater or stadium screen, or a sign. Various control mechanisms may be used to control devices fabricated in accordance with the present invention, including passive matrix and active matrix. Many of the devices are intended for use in a temperature range comfortable to humans, such as 18 C to 30 C, and more preferably at room temperature (20-25 C), but could be used outside this temperature range, for example, from −40 C to +80 C.

Many devices that incorporate OLEDs, such as displays and lighting panels, may benefit from reliable protection from atmospheric gases. In particular, moisture and oxygen may damage or cause degradation of OLEDs and OLED panels over time, thus reducing the performance of the device. For example, many chemically-reactive low work function metals often used as electrodes are unstable in the presence of these species and can oxidize and delaminate from the underlying organic layer, causing dark spots. Many common techniques used for film encapsulation techniques of OLEDs use a first layer of inorganic metal oxide or hybrid organic-inorganic oxide deposited directly on top of the cathode or capping layer. Oxygen-containing reactive gases used in such a deposition process, as well as the byproducts generated during the deposition process, also may initiate dark spot formation, which may be detrimental for long term operation of OLEDs.

To address this problem, novel buffer layers for OLEDs and OLED-containing devices are disclosed herein, which may separate the oxygen-containing materials in a barrier or other layer from oxygen-sensitive layers of the OLED. In an embodiment, a buffer layer may be disposed over the cathode/capping layer prior to deposition of a metal oxide or hybrid organic-inorganic oxide layer. The buffer layer may be fabricated without the use of oxygen-containing reactive gases, thereby reducing or eliminating exposure of the cathode to oxygen and other byproducts. To further understand the significance of this buffer layer, it may be useful to examine the fabrication, contents, and attributes of conventional barrier layers used in the field.

As previously disclosed, cathode materials used for OLEDs often have a relatively low to medium work function. For example, Ca has a work function of 2.87 eV; Al has a work function of 4.3 eV; and Mg (for example in Mg:Ag layers) has a work function of 3.66eV. Low work function metals may be highly sensitive to oxygen and moisture, and can delaminate from the underlying organic layer upon reaction. Further, commonly used organic emitting materials can form non-emissive quenching species upon exposure to water.

In conventional arrangements, OLEDs are protected from such materials by encapsulating the OLEDs and a desiccant between two glass plates, which are sealed around the edge with an adhesive. This traditional encapsulation method makes the display rigid, and hence cannot be used for encapsulating flexible OLEDs. Hence, there is also a need for relatively thin, flexible encapsulation to allow for fabrication of OLED displays that are lightweight, long lasting, and/or flexible.

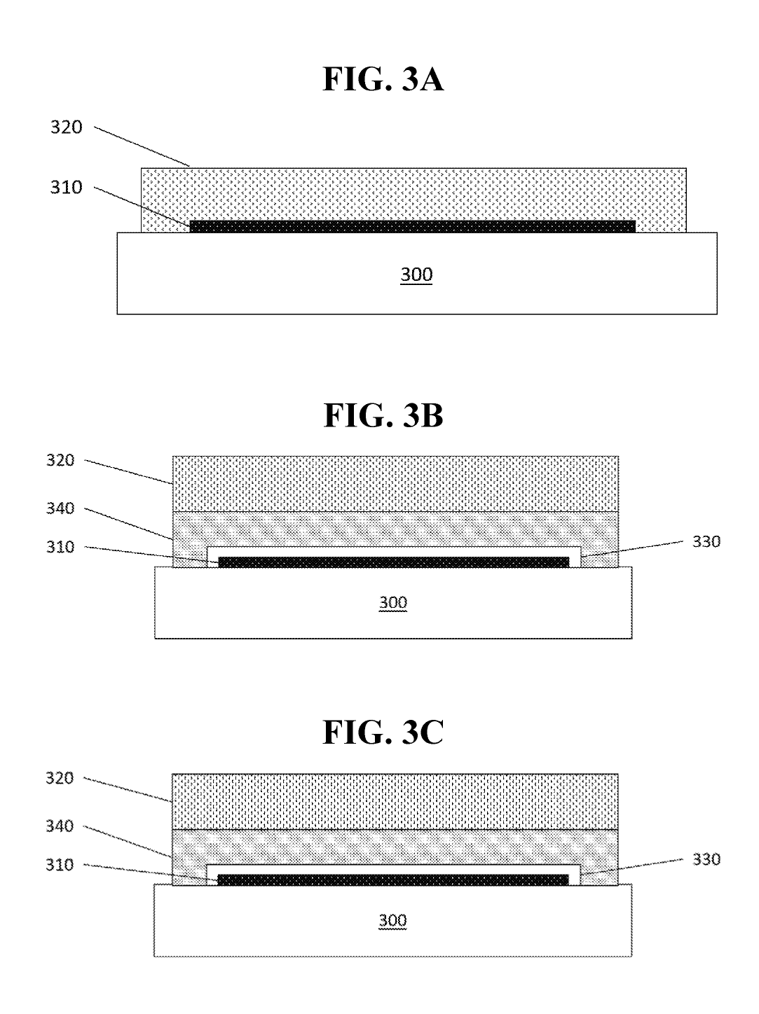

Thin film encapsulation of an OLED or similar device may be performed using direct encapsulation, indirect encapsulation, or a combination thereof In direct encapsulation, the barrier film is deposited over the OLED. For example, a barrier film may be deposited over the cathode or cathode capping layer of the device. FIG. 3A shows a schematic view of an OLED device with a direct encapsulation barrier layer. In such an arrangement, an OLED 310 is disposed over a substrate 300 or other foundation, and the barrier layer or layers 320 are disposed over the OLED device 310. The substrate may be rigid or flexible, and may include materials such as glass, barrier-coated polymers, and metal foils.

In indirect encapsulation techniques, a barrier-coated film is laminated over the OLED device. FIG. 3B shows a schematic of an OLED device encapsulated via indirect encapsulation. Typically, a passivation layer 330 is disposed over the OLED 310 before an adhesive, adhesive desiccant mixture, or similar layer 340. The barrier layer 320 is then deposited over the adhesive layer 340.

Additionally, a combination of direct and indirect encapsulation may be used, as shown in FIG. 3C. In such an arrangement, barrier layers 320 may be deposited over the OLED 310 and over an adhesive layer 340.

Regardless of whether direct, indirect, or both encapsulation techniques are used, at least one surface of the display should be protected with a barrier film that is at least partially transparent, to transmit the light generated by the OLEDs. Conventionally, direct encapsulation often is preferred for flexible devices, as it may provide an inherent edge seal. Conversely, direct encapsulation is also challenging as the barrier deposition process needs to be compatible with the underlying OLED device. Specifically, it often will be necessary for the barrier film to be deposited at temperatures below the glass transition temperature of the organic materials used in the OLED. In addition, the reactive gases, byproducts and deposition process should not damage the cathode, organic layers, or other layers of the device. Such damage may include oxidation, bulk delamination of the cathode from the underlying organic layer or layers, local delamination of the cathode from the underlying organic layer or layers, micro shorts, leakage, and the like. Similarly, the same constraints may apply to a passivation layer that is deposited before indirect encapsulation.

Conventional barrier materials used for direct thin film encapsulation include inorganic and hybrid organic-inorganic metal oxides, nitrides, and oxy-nitrides. A single layer, pure inorganic thin film barrier develops self-relief micro-cracks once it reaches a critical thickness. Further, these barrier layers contain microscopic defects when deposited at low temperatures. These defects may form pathways for permeation of atmospheric gases such as oxygen and water vapor. Accordingly, a single pure inorganic barrier layer generally is not effective in protecting the OLED.

To provide further protection to an OLED, a multi-layer barrier may be used, such as those disclosed in U.S. Pat. No. 6,268,695 teaches the use of ‘multiple’ barrier stacks/dyads to encapsulate moisture sensitive devices (such as OLEDs) and substrates. Each barrier stack or “dyad” consists of an inorganic material/polymer layer pair. The polymer layer is usually a polyacrylate material, which is deposited by flash evaporation of a liquid acrylate monomer that is subsequently cured by UV radiation or an electron beam. Such a polymer layer may mechanically decouple “defects” in the inorganic layers, as disclosed in U.S. Pat. No. 6,570,325. By using multiple dyads, typically around 3 to 5 dyads (6 to 10 layers), these barrier films may protect the underlying device by mechanically de-coupling the rigid inorganic layers from each other and by forcing long permeation paths on water and oxygen, so that these molecules take long times to reach the OLED. Although such techniques may provide a relatively long lag time for top-down diffusion of water vapor through the dyads, they may not address the lateral or edge diffusion of water vapor. Since the polymer/decoupling layer has a high diffusion co-efficient for water vapor, a very wide edge seal may be required for protection. As disclosed in U.S. Pat. No. 7,198,832, the edge seal width may be reduced if the area of the inorganic barrier layer is made larger than the area of the decoupling (i.e. the polymer layer). Subsequently, the area of the second barrier stack may be larger than the area of the first barrier stack, and so on. By adopting this structure, the barrier layer may provide protection against lateral/edge diffusion of water vapor and oxygen. However, such a structure fundamentally imposes a limit on the minimum edge width obtainable. Since the “edge width” or “bezel width” is a non-usable portion of the display, such techniques may make it almost impossible to obtain an almost zero-edge or an edgeless display.

In addition, the equipment and processes typically used for the deposition of polymeric and inorganic layers are completely different, thus making a multilayer barrier relatively expensive and time consuming. Inorganic barriers can be deposited by a multitude of vacuum deposition techniques such as sputtering, evaporation, e-beam, atomic layer deposition (ALD), plasma enhanced chemical vapor deposition (PECVD), plasma assisted atomic layer deposition, and combinations thereof. The polymer layer may be deposited by flash evaporation, ink jet printing, screen printing, slot die coating, and the like. Thus, a substrate will be transferred from a vacuum chamber (inorganic deposition) to an inert atmosphere chamber (non-vacuum) to flash evaporate the monomer layer and cure it, and vice versa. Multiple transfers between chambers and intervening masking steps for barrier overlap considerably increase the cost, complexity, and likelihood of contamination or failure of such a process.

In contrast to multi-layer barriers, barriers made of a single material in one apparatus may be desirable due to the lower complexity and cost of fabrication. U.S. Pat. No. 7,968,146 describes one such SiOxC_{y}H_{z} hybrid barrier layer, which may be grown by plasma enhanced chemical vapor deposition (PECVD) of an organic precursor with a reactive gas such as oxygen, e.g., HMDSO/O₂. Such a barrier film may be highly impermeable yet flexible. The material is a hybrid of inorganic SiO₂ and polymeric silicone that is deposited at room temperature. The barrier film typically has permeation and optical properties of glass, but with a partial polymer character that gives a thin barrier film low permeability and wide range of flexibility. At room temperature, a layer of this hybrid material is free of micro-cracks when deposited approximately thicker than 100 nm.

In both the single hybrid and multilayer barrier approach used for direct encapsulation of OLEDs, a first layer of inorganic or a hybrid oxide barrier may be deposited on top a cathode or capping layer, thus achieving a structure as shown in FIG. 3A. Commonly used first inorganic metal oxides are AlO₃ as described in U.S. Pat. No. 6,548,912, Zn₂SnO₄, SiO₂, TiO₂, and ZnO. These oxides generally are deposited by reactive sputtering of the target material with oxygen or oxygen-containing reactive gas to achieve the desired stoichiometry, morphology and optical properties. Alternatively, they can also be deposited by PECVD, ALD, plasma assisted evaporation, plasma assisted ALD with oxygen or oxygen containing reactive gas. Similarly, a commonly used hybrid oxide layer is SiOₓC_{y}H_{z}. This can be made by PECVD of HMDSO with oxygen or nitrous oxide. In any plasma process (sputtering, PECVD, PE-ALD) with oxygen, the plasma consists of O+, O−, O2+, O*, neutral and ionized O3, and electrons. The oxygen radicals are chemically unstable and highly reactive. During direct encapsulation of OLEDs, the cathode is subjected to the oxygen free radicals until the formation of a first continuous barrier layer. Any defects in the cathode may cause selective organic-cathode interface oxidation, thus leading to cathode delamination and causing dark spots in the resulting OLED. Furthermore, if the precursor or other reactive gases contain hydrogen, byproducts such as water vapor can be generated which may again lead to dark spot formation as explained by Aziz et al. and Liew et al. For example, the byproducts of plasma polymerization of HMDSO/O₂ may include water and oxygen as described by Hegemann et al. These species also may initiate dark spots in the resulting OLED, which may continue to grow after fabrication of the OLED.

To prevent such dark spot formation, it has been found that a buffer layer may be disposed over the OLED cathode/capping layer, prior to the metal oxide or hybrid oxide deposition. As disclosed herein, such a buffer layer may prevent or reduce the undesirable effects of barrier layer deposition techniques on the OLED by preventing barrier layer materials, and/or byproducts of the deposition process used to fabricate barrier layers, from interacting chemically or otherwise with the underlying OLED or individual layers of the underlying OLED.

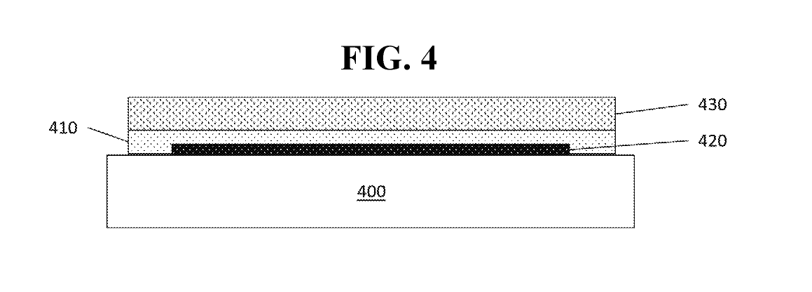

In an embodiment, a buffer layer is disposed over a cathode/capping layer or other layer of an OLED prior to deposition of a metal oxide or hybrid organic-inorganic oxide barrier over the OLED. FIG. 4 shows a schematic of an OLED structure including a buffer layer as disclosed herein. The OLED may have a structure such as shown in FIGS. 1-2, or any other OLED structure known in the art. As shown in FIG. 4, a buffer layer 410 as disclosed herein may be disposed over an OLED 420 disposed on a substrate 400. A barrier layer 430 as previously described may be disposed over the buffer layer. Notably, the buffer layer 410 is fabricable without the use of an oxygen-containing gas, i.e., the buffer layer may be deposited or otherwise fabricated over the OLED without using any oxygen-containing gases as part of the deposition process. Thus, even if oxygen-containing gases are used during the fabrication process of the barrier layer 430, the bufferlayer may separate the oxygen-containing materials from the oxygen-sensitive layers of the OLED. The buffer layer may consist essentially of one or more materials that is fabricable without the use of an oxygen-containing gas, i.e., it may include only trace, miniscule, or undetectable amounts of other materials, such that the presence of the other materials is insufficient to affect the properties of the buffer layer. Preferably, any such trace materials will be insufficient to damage any layers of an underlying OLED. Preferably, the buffer layer may consist entirely of materials that are fabricable without the use of an oxygen-containing gas, i.e., it may include only such materials. Although FIG. 4 shows a single barrier layer 430 for ease of illustration, it will be understood that other barrier layers may be deposited on any side of the device in addition to the single barrier layer shown. For example, additional barrier layers may be deposited over the barrier layer 430, or on the opposite side of the substrate 400 (i.e., below and/or encapsulating the substrate and/or other layers).

As previously disclosed, it may be preferred to deposit a buffer layer as disclosed herein in the same chamber as a barrier layer that is deposited over the buffer layer. In an embodiment, the buffer layer and subsequent barrier layer may be done in the same chamber. In other aspects of the current embodiment, the buffer layer and the subsequent barrier layer may be done by the same process. For example, a buffer layer of SiOxCyHz, may be obtained by plasma polymerization of HMDSO, HMDSO/Ar, HMDSO/He, or the like. A subsequent barrier layer may be fabricated by plasma polymerization of HMDSO/O2 or HMDSO/N2O. Using a single process and chamber to deposit both the buffer layer and the barrier layer may significantly reduce the complexity of device fabrication, improve the efficiency and lifetime of the device, and reduce TACT time and cost.

In some embodiments, a buffer layer as disclosed herein may be fabricated from a single material or different materials. For example, if the materials are deposited by sputtering, sputtering targets of different compositions can be used to obtain this layer. Alternatively, two targets of same composition can be used with different non-oxygen containing reactive gases. Two different types of deposition sources could be used.

A buffer layer as disclosed herein may be amorphous or polycrystalline. For example, thin films of SiOxCyHz deposited by plasma polymerization are typically amorphous. Thin films of aluminum oxide deposited by sputtering from an aluminum oxide target are typically polycrystalline.

The thickness of a buffer layer as disclosed herein may range from 5 nm to 1500 nm, depending on the choice of materials, process, and the final application. In some embodiments, a thinner buffer layer may be desirable to maintain a relatively thin device profile. For example, it may be preferred for the buffer layer to be 5 nm-500 nm in thickness. In some embodiments it may be preferred for the buffer layer to be 5-1500 nm, more preferably 5-500 nm, including all portions of the buffer layer. Alternatively, in embodiments in which the buffer layer includes multiple portions, such as portions containing different materials or different ratios of the same material, each portion may be 5-1500 nm, more preferably 5-500 nm, in thickness.

A buffer layer as disclosed herein may encapsulate an underlying OLED or layer. As used herein, a first layer “encapsulates” a second layer if the first layer surrounds all sides of the second layer that are not already in direct physical contact with another layer. For example, referring to FIG. 4, the buffer layer 410 will be said to encapsulate the OLED 420 if the buffer layer extends completely across every surface of the OLED, other than the surface in contact with the substrate 400, such that the buffer layer at least completely covers each surface.

Suitable materials for a buffer layer as disclosed herein include, without limitation, metals, metal oxides, metal nitrides, metal oxy-nitrides, metal carbides, metal oxy-borides and hybrid organic-inorganic materials and combinations thereof. In all the cases, no oxygen containing reactive gas is required to deposit the buffer layer.

Metals for use in a buffer layer as disclosed herein may preferably be selected from Al, Ni, Cr, Au, Ti, Pt, Ag, Mg, Yb and combinations thereof. Metal oxides may be preferably selected from silicon oxide, aluminum oxide, indium oxide, tin oxide, zinc oxide, indium tin oxide, indium zinc oxide, aluminum zinc oxide, zinc tin oxide, tantalum oxide, zirconium oxide, niobium oxide, molybdenum oxide and combinations thereof. Metal nitrides may be preferably selected from silicon nitride, aluminum nitride, boron nitride, titanium nitride and combinations thereof. Metal oxy-nitrides may be preferably selected from aluminum oxy-nitride, silicon oxy-nitride, boron oxy-nitride and combinations thereof. Metal carbides may be preferably selected from tungsten carbide, boron carbide, silicon carbide and combinations thereof. Metal oxy-borides may be preferably zirconium oxy-boride, titanium oxy-boride and combinations thereof. Hybrid organic-inorganic materials may include, but are not limited to SiOxCyHz, SiOxNyHz, SiOxNyCz, SiOxNyCz,H, SiOxCyHzF, SiOxNyHzF, SiOxNyCzF, SiOxNyCz,HaF, AlOxCyHz, AlOxNyHz, AlOxNyCz, AlOxNyCz,H, AlOxCyHzF, AlOxNyHzF, AlOxNyCzF, AlOxNyCz,HaF, ZnOxCyHz, ZnOxNyHz, ZnOxNyCz, ZnOxNyCz,H, ZnOxCyHzF, ZnOxNyHzF, ZnOxNyCzF, ZnOxNyCz,HaF, TiOxCyHz, TiOxNyHz, TiOxNyCz, TiOxNyCz,H, TiOxCyHzF, TiOxNyHzF, TiOxNyCzF, TiOxNyCz,HaF.

A buffer layer as disclosed herein may be fabricated using a vacuum deposition process, such as PVD and/or CVD, without using oxygen-containing reactive gas. Physical vapor deposition methods may include, but are not limited to sputtering, evaporation, and e-beam. Chemical vapor deposition methods may include, but are not limited to atomic layer deposition (ALD), plasma enhanced chemical vapor deposition (PECVD), and plasma assisted atomic layer deposition and combinations thereof.

For example, an Indium Zinc Oxide (IZO) buffer layer may be fabricated by RF/DC sputtering an IZO target without any oxygen containing reactive gas. Other non-oxygen containing gases may be added to alter the properties of the resulting film. Similarly, a buffer layer of SiOxCyHz may be obtained by plasma polymerization of HMDSO, HMDSO/Ar, HMDSO/He, or the like. Suitable non-oxygen containing reactive gases for use with PVD and CVD techniques may include, but are not limited to He, Ne, Ar, Kr, Xe, Rn, N2, NH3, NF3, SiF, F2, CF4, C2F6, SF6.

When a buffer layer as disclosed herein is fabricated by physical vapor deposition, preferred target materials may include, but are not limited to Al, Ni, Cr, Au, Ti, Pt, Ag, Mg, Yb, silicon oxide, aluminum oxide, indium oxide, tin oxide, zinc oxide, indium tin oxide, indium zinc oxide, aluminum zinc oxide, tantalum oxide, zirconium oxide, niobium oxide, molybdenum oxide, silicon nitride, aluminum nitride, boron nitride, titanium nitride, aluminum oxy-nitride, silicon oxy-nitride, boron oxy-nitride, tungsten carbide, boron carbide, silicon carbide, zirconium oxy-boride, titanium oxy-boride and combinations thereof.

When a buffer layer as disclosed herein is fabricated by chemical vapor deposition, precursors materials may include, but are not limited to hexamethyl disiloxane (HMDSO) and tetrathylorthosilicate (TEOS); methylsilane; dimethylsilane (DMS); vinyl trimethylsilane; trimethylsilane; tetramethylsilane; ethylsilane; disilanomethan

e; bis(methylsilano)methane; 1,2-disilanoethane; 1,2-bis(methylsilano)ethane; 2,2-disilanopropane; 1,3,5-trisilano-2,4,6-trimethylene; dimethylphenylsilane; diphenylmethylsilane; tetraethylortho silicate; dimethyldimethoxysilane; 1,3,5,7-tetramethylcyclotetrasiloxane; 1,3-dimethyldisiloxane; 1,1,3,3-tetramethyldisiloxane; 1,3-bis(silanomethylene)disiloxane; bis(1-methyldisiloxanyl)methane; 2,2-bis(1-methyldisiloxanyl)propane; 2,4,6,8-tetramethylcyclotetrasiloxane; octamethylcyclotetrasiloxane; 2,4,6,8,10-pentamethylcyclopentasiloxane; 1,3,5,7-tetrasilano-2,6-dioxy-4,8-dimethylene; hexamethylcyclotrisiloxane; 1,3,5,7,9-pentamethylcyclopentasiloxane; hexamethoxydisiloxane; hexamethyldisilazane (HMDS); divinyltetramethyldisilizane; hexamethylcyclotrisilazane; dimethylbis(Nmethylacetamido)silane; dimethylbis-(N-ethylacetamido)silane; methylvinylbis(Nmethylacetamido)silane; methylvinylbis(N-butylacetamido)silane; methyltris(Nphenylacetamido)silane; vinyltris(N-ethylacetamido)silane; tetrakis(N-methylacetamido)silane; diphenylbis(diethylaminoxy)silane; methyltris(diethylaminoxy)silane; and bis(trimethylsilyl)carbodiimide, diethyl zinc, dimethyl zinc, zinc acetate, titanium tetrachloride, tetrakis-dimethylamidotitanium (TDMAT) and tetrakis-diethylamidotitanium(TDEAT), titanium ethoxide, titanium isopropoxide, titanium tetraisopropoxide, aluminum isopropoxide, trimethyl aluminum, dimethyltin diacetate, zinc acetylacetonate, zirconium hexafluoroacetylacetonate, trimethyl indium, triethyl indium, cerium (IV) (2,2,6,6-tetramethyl-3,5-heptanedionate), and zinc carbamate.

Barrier layers deposited over a buffer layer as disclosed herein may include any of the barrier layers described or referenced herein including, without limitation, single- and multilayer barrier films, hybrid barrier films, and the like.

A buffer layer as disclosed herein may solve several problems and provide several advantages over conventional arrangements and techniques. For example, a buffer layer as disclosed herein may protect a cathode and/or capping layer of an OLED from oxygen- and water vapor-induced damage during a subsequent barrier film deposition step. As previously disclosed, because a buffer layer as disclosed herein may be fabricated without using oxygen containing reactive gases, the cathode exposure to oxygen and other byproducts during the buffer layer deposition may be reduced or eliminated. Unlike some conventional techniques, a buffer layer may be deposited at temperatures below the glass transition temperature of the organic materials used in OLED devices. The buffer layer also may form a continuous coating and provide a suitable surface for subsequent barrier growth, thus allowing for a device to obtain the benefit of various barrier layer techniques and arrangements, without the risk of damage to the underlying OLED.

### Experimental

Two transparent OLEDs (Devices A and B) with highly reactive Mg:Ag cathodes were grown on glass substrates. Device A was subsequently encapsulated with a 4 micron thick single hybrid SiOxCyHz barrier layer deposited by plasma polymerization of HMDSO with oxygen. Device B was capped with a 50 nm Indium zinc oxide (IZO) inventive buffer layer prior to encapsulation. This IZO buffer layer was deposited by DC sputtering of an In2O3: ZnO target (90:10) with Ar as the reactive gas. No oxygen containing reactive gas was used for the IZO deposition.

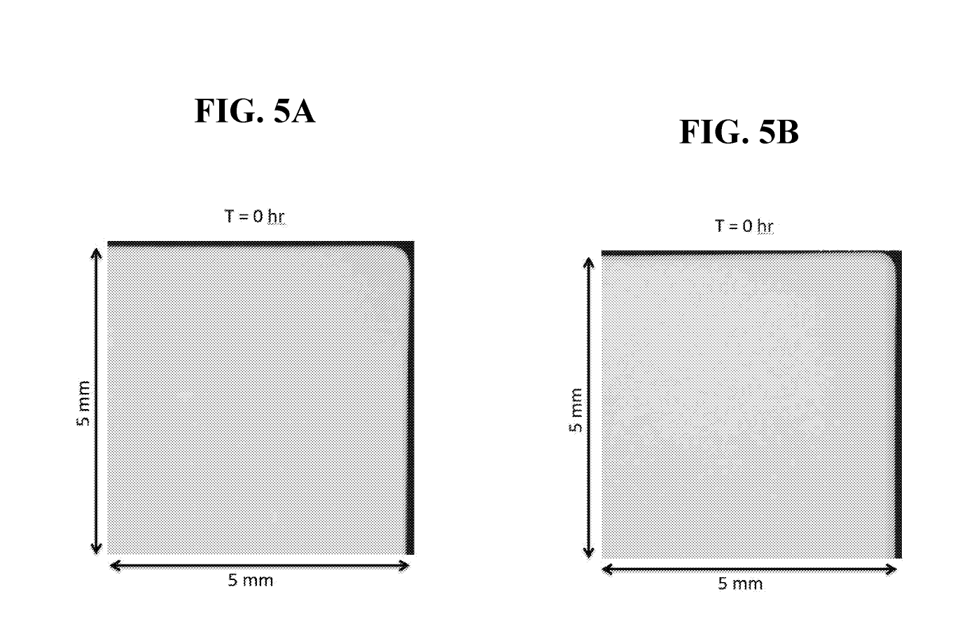

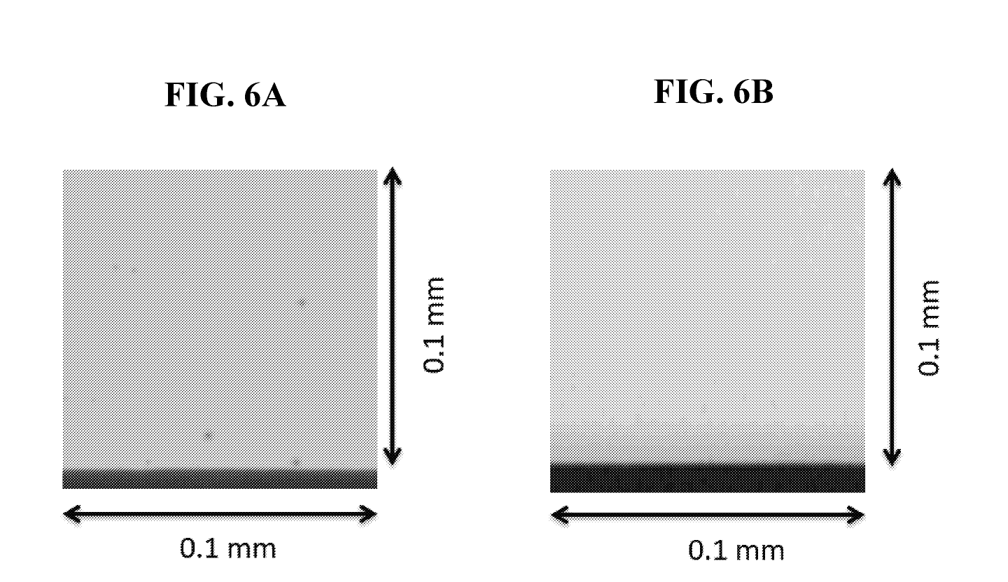

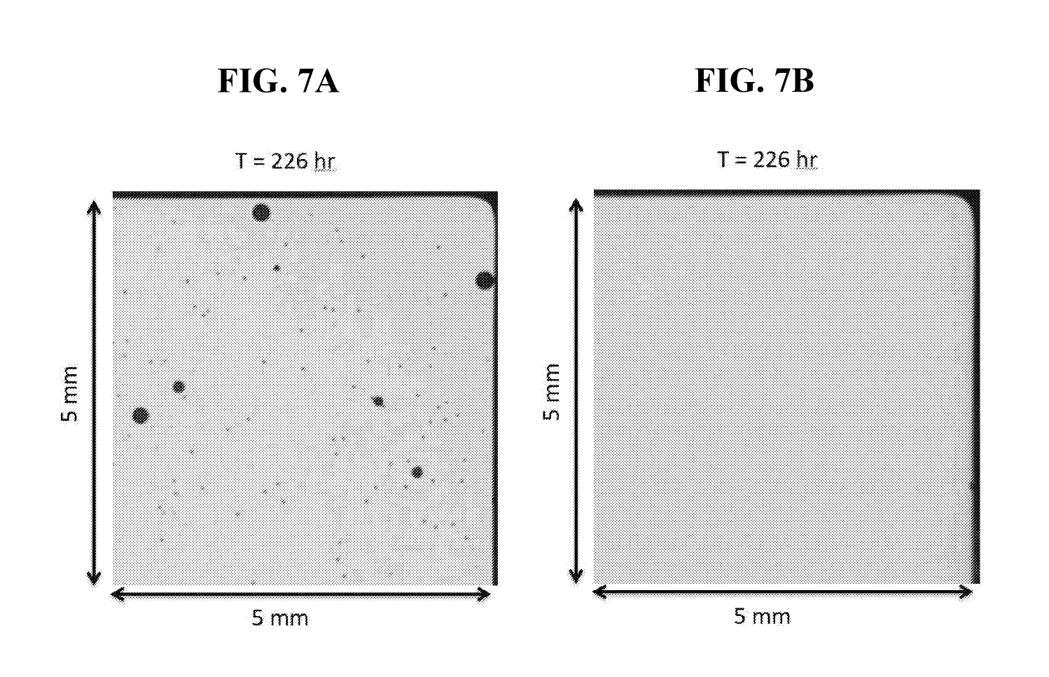

The devices were monitored in air (23C, 50% relative humidity). FIGS. 5A and 5B show photographs of the OLED Devices A and B at T=0 hours, respectively. Both the pixels look defect free under low magnification. However, Device A revealed numerous small dark spots (<5 um) under higher magnification while Device B is free of dark spots as seen in FIGS. 6A and 6B, which show photographs of the same devices as in FIGS. 5A and 5B, respectively. The dark spot seeds in Device A may have been created during the hybrid barrier layer deposition in the PECVD; i.e.: oxygen plasma and water by-product. FIGS. 7A and 7B show images of the same device pixels as in FIGS. 5A-5B and 6A-6B, respectively, at T=226 hours. It was observed that the dark spots in Device A continue to grow and became visible under low magnification, while Device B remained free of dark spots. The IZO buffer layer on Device B prevented the dark spot initiation during the deposition of the barrier layer. Thus, as previously disclosed, it was found that the buffer layer as disclosed herein operated to prevent the formation of dark spots caused by damage to the OLED layers.

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

1.-16. (canceled)

17. A method comprising:
depositing a buffer layer over an OLED disposed on a substrate; and
depositing a first barrier layer over the buffer layer, the first barrier layer comprising one or more materials selected from the group consisting of: a metal oxide, a hybrid organic-inorganic oxide, a metal nitride, a metal oxy-nitride, a metal carbide, a metal oxy-boride barrier material, and a combination thereof;
wherein the buffer layer consists essentially of one or more materials that is fabricable without the use of an oxygen-containing gas, and
wherein the buffer layer is deposited at a temperature lower than a glass transition temperature of an organic material disposed within the OLED.

18. (canceled)

19. The method of claim 17, wherein the first barrier layer is deposited in the same chamber as the buffer layer without removing the OLED and the buffer layer from the chamber.

20. The method of claim 17, further comprising depositing a second barrier layer over the first barrier layer.

21. The method of claim 17, wherein the buffer layer and the first barrier layer are deposited using the same process.

22. The method of claim 17, wherein the buffer layer comprises multiple materials.

23. The method of claim 17, wherein the buffer layer is deposited using a technique selected from the group consisting of: physical vapor deposition (PVD), chemical vapor deposition (CVD), plasma polymerization, or a combination thereof

24. The method of claim 23, wherein the buffer layer is deposited using a PVD process selected from the group consisting of: sputtering, evaporation, and e-beam deposition, and a combination thereof, using a target comprising one or more materials selected from the group consisting of Al, Ni, Cr, Au, Ti, Pt, Ag, Mg, Yb, silicon oxide, aluminum oxide, indium oxide, tin oxide, zinc oxide, indium tin oxide, indium zinc oxide, aluminum zinc oxide, tantalum oxide, zirconium oxide, niobium oxide, molybdenum oxide, silicon nitride, aluminum nitride, boron nitride, titanium nitride, aluminum oxy-nitride, silicon oxy-nitride, boron oxy-nitride, tungsten carbide, boron carbide, silicon carbide, zirconium oxy-boride, titanium oxy-boride and combinations thereof.

25. The method of claim 23, wherein the buffer layer is deposited using a PVD process using a target comprising one or more materials selected from the group consisting of: Al, Ni, Cr, Au, Ti, Pt, Ag, Mg, Yb, silicon oxide, aluminum oxide, indium oxide, tin oxide, zinc oxide, indium tin oxide, indium zinc oxide, aluminum zinc oxide, tantalum oxide, zirconium oxide, niobium oxide, molybdenum oxide, silicon nitride, aluminum nitride, boron nitride, titanium nitride, aluminum oxy-nitride, silicon oxy-nitride, boron oxy-nitride, tungsten carbide, boron carbide, silicon carbide, zirconium oxy-boride, titanium oxy-boride and combinations thereof.

26. The method of claim 23, wherein the buffer layer is deposited using a CVD process selected from the group consisting of: atomic layer deposition (ALD), plasma enhanced chemical vapor deposition (PECVD), and plasma assisted atomic layer deposition and a combination thereof

27. The method of claim 23, wherein the buffer layer is deposited using a CVD process selected from the group consisting of: atomic layer deposition (ALD), plasma enhanced chemical vapor deposition (PECVD), and plasma assisted atomic layer deposition and a combination thereof, using a precursor comprising one or more materials selected from the group consisting of: hexamethyl disiloxane (HMDSO) and tetrathylorthosilicate (TEOS); methylsilane; dimethylsilane (DMS); vinyl trimethylsilane; trimethylsilane; tetramethylsilane; ethylsilane; disilanomethane; bis(methylsilano)methane; 1,2-disilanoethane; 1,2-bis(methylsilano)ethane; 2,2-disilanopropane; 1,3,5-trisilano-2,4,6-trimethylene; dimethylphenylsilane; diphenylmethylsilane; tetraethylortho silicate; dimethyldimethoxysilane; 1,3,5,7-tetramethylcyclotetrasiloxane; 1,3-dimethyldisiloxane; 1,1,3,3-tetramethyldisiloxane; 1,3-bis(silanomethylene)disiloxane; bis(1-methyldisiloxanyl)methane; 2,2-bis(1-methyldisiloxanyl)propane; 2,4,6,8-tetramethylcyclotetrasiloxane; octamethylcyclotetrasiloxane; 2,4,6,8,10-pentamethylcyclopentasiloxane; 1,3,5,7-tetrasilano-2,6-dioxy-4,8-dimethylene; hexamethylcyclotrisiloxane; 1,3,5,7,9-pentamethylcyclopentasiloxane; hexamethoxydisiloxane; hexamethyldisilazane (HMDS); divinyltetramethyldisilizane; hexamethylcyclotrisilazane; dimethylbis(Nmethylacetamido)silane; dimethylbis-(N-ethylacetamido)silane; methylvinylbis(Nmethylacetamido)silane; methylvinylbis(N-butylacetamido)silane; methyltris(Nphenylacetamido)silane; vinyltris(N-ethylacetamido)silane; tetrakis(N-methylacetamido)silane; diphenylbis(diethylaminoxy)silane; methyltris(diethylaminoxy)silane; and bis(trimethylsilyl)carbodiimide, diethyl zinc, dimethyl zinc, zinc acetate, titanium tetrachloride, tetrakis-dimethylamidotitanium (TDMAT) and tetrakis-diethylamidotitanium(TDEAT), titanium ethoxide, titanium isopropoxide, titanium tetraisopropoxide, aluminum isopropoxide, trimethyl aluminum, dimethyltin diacetate, zinc acetylacetonate, zirconium hexafluoroacetylacetonate, trimethyl indium, triethyl indium, cerium (IV) (2,2,6,6-tetramethyl-3,5-heptanedionate), and zinc carbamate and combinations thereof.

28. A device prepared by a process comprising the method of:
depositing a buffer layer over an OLED disposed on a substrate; and
depositing a first barrier layer over the buffer layer, the first barrier layer comprising one or more materials selected from the group consisting of: a metal oxide, a hybrid organic-inorganic oxide, a metal nitride, a metal oxy-nitride, a metal carbide, a metal oxy-boride barrier material, and a combination thereof;
wherein the buffer layer consists essentially of one or more materials that is fabricable without the use of an oxygen-containing gas, and
wherein the buffer layer is deposited at a temperature lower than a glass transition temperature of an organic material disposed within the OLED.
